(19) United States
(12) Patent Application Publication
(10) Pub. No.: US 2008/0003707 A1
(43) Pub. Date: Jan. 3, 2008

(54) Method for fabricating diode having reflective electrode of alloy metal

(75) Inventors: Cheng-Yi Liu, Taoyuan County (TW); Chia-Hsien Chou, Taipei County (TW); Ching-Liang Lin, Taipei County (TW)

Correspondence Address: TROXELL LAW OFFICE PLLC, 5205 LEESBURG PIKE, SUITE 1404, FALLS CHURCH, VA, 22041, US

(73) Assignee: National Central University, Taoyuan (TW)

(21) Appl. No.: 11/501,015

(22) Filed: Aug. 9, 2006

(30) Foreign Application Priority Data
Jun. 29, 2006 (TW) 095123583

(51) Int. Cl. H01L 33/00

(52) U.S. Cl. 438/29; 438/46; 438/39

(57) ABSTRACT

The present invention provides a method to fabricate a diode whose heat stability is improved. The diode has a layer of high reflective ohmic contact and an alloy metal is used in the layer. With the alloy metal used in the layer, the heat stability of the diode is improved.

### FIELD OF THE INVENTION

The present invention relates to fabricating a diode; more particularly, relates to fabricating a high reflective ohmic contact alloy layer in the diode to improve a heat stability of the diode

### DESCRIPTION OF THE RELATED ARTS

A first prior art, “A novel light emitting diode (LED)”, is proclaimed in Taiwan, comprising a substrate, a base and a crystal grain, where the substrate has at least one through-hole and a plurality of contacts; the through-hole penetrates through the substrate; the base is located in the through-hole; the crystal grain is deposed on a surface of the base where the surface is plated with a reflective metal layer; and the metal layer is made of silver or tin.

A second prior art is proclaimed in Taiwan, “A LED and a fabricating method thereof.” The second prior art comprises a substrate; a semiconductor layer deposed on the substrate; a plurality of electrodes deposed on the semiconductor layer; a protecting layer deposed on the semiconductor layer with a plurality of openings to expose the plurality of electrodes; a bottom layer of a plurality of metal balls deposed on the plurality of electrodes; and a light reflective layer deposed on the protecting layer and electrically insulated from the electrodes and the bottom layer, where the bottom layer is made of the same material as the light reflective layer; and the material is gold, silver or titanium/tungsten.

Each of the above prior arts has a layer of a pure metal. But the metal will be aggregated after a thermal treatment so that the current in the diode is not distributed evenly and contact resistances differ very much so as to weaken the light emitted. Hence, the prior arts do not fulfill users′ requests on actual use.

### SUMMARY OF THE INVENTION

The main purpose of the present invention is to fabricate a diode where a heat stability of the diode is effectively improved by using a metal alloy in a high reflective ohmic contact layer of the diode.

To achieve the above purpose, the present invention is a method for fabricating a diode having a reflective electrode of an alloy metal. A first embodiment comprises steps of: (a) obtaining a p-side up gallium nitride (GaN) wafer comprising a first substrate, a buffer layer and an epitaxy layer; (b) forming a p-GaN mesa through a lithography and an etching on the epitaxy layer of the p-side up GaN wafer; (c) plating an alloy metal layer on the p-GaN mesa and processing a thermal treatment to a surface of the alloy metal layer to form a high reflective ohmic contact alloy layer; (d) forming an n-pad through a lithography and a metal depositing process on the p-side up GaN wafer; (e) forming a p-pad through a lithography and a metal depositing process on the high reflective ohmic contact alloy layer; and (f) packaging a structure, obtained through step (a) to step (e), on a second substrate through a packaging process of flip chip with a metal material to connect the second substrate to the structure.

A second embodiment comprises steps of: (a1) obtaining a p-side up GaN wafer comprising a first substrate, a buffer layer and an epitaxy layer; (b1) plating an alloy metal layer on the epitaxy layer of the p-side up GaN wafer and forming a high reflective ohmic contact alloy layer through a thermal treatment on a surface of the alloy metal layer; (c1) obtaining a conjoining layer to conjoin the high reflective ohmic contact alloy layer and a third substrate; (d1) processing a laser lift-off process to lift the first substrate and the buffer layer off the epitaxy layer of the p-side up GaN wafer; and (e1) forming an n-pad on the epitaxy layer through a lithography and a metal depositing process.

A third embodiment comprises steps of: (a2) obtaining a p-side up GaN wafer comprising a first substrate, a buffer layer and an epitaxy layer; (b2) forming a p-GaN mesa through a lithography and an etching on the epitaxy layer of the p-side up GaN wafer; (c2) forming a transparency conductive layer (TCL layer) on the p-GaN mesa; (d2) forming an n-pad through a lithography and a metal depositing process on the p-side up GaN wafer; (e2) forming a p-pad through a lithography and a metal depositing process on the TCL layer; and (f2) plating an alloy metal layer on a bottom surface of the first substrate of the p-side up GaN wafer and forming a high reflective ohmic contact alloy layer through a thermal treatment on a surface of the alloy metal layer.

Accordingly, a novel method for fabricating a diode having a reflective electrode of an alloy metal is obtained.

### BRIEF DESCRIPTIONS OF THE DRAWINGS

The present invention will be better understood from the following detailed descriptions of the preferred embodiments according to the present invention, taken in conjunction with the accompanying drawings, in which

FIG. 1 is the view showing the flow chart of the first preferred embodiment according to the present invention;

FIG. 2A is the structural view of the first preferred embodiment;

FIG. 2B is the structural view of the p-side up GaN wafer;

FIG. 3 is the flow-chart view of the second preferred embodiment;

FIG. 4 is the structural view of the second preferred embodiment;

FIG. 5 is the flow-chart view of the third preferred embodiment; and

FIG. 6 is the structural view of the third preferred embodiment.

### DESCRIPTION OF THE PREFERRED EMBODIMENTS

The following descriptions of the preferred embodiments are provided to understand the features and the structures of the present invention.

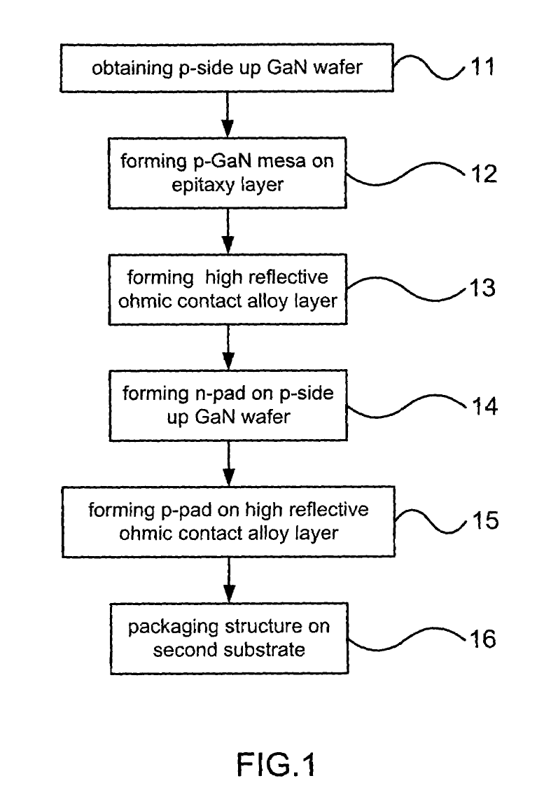

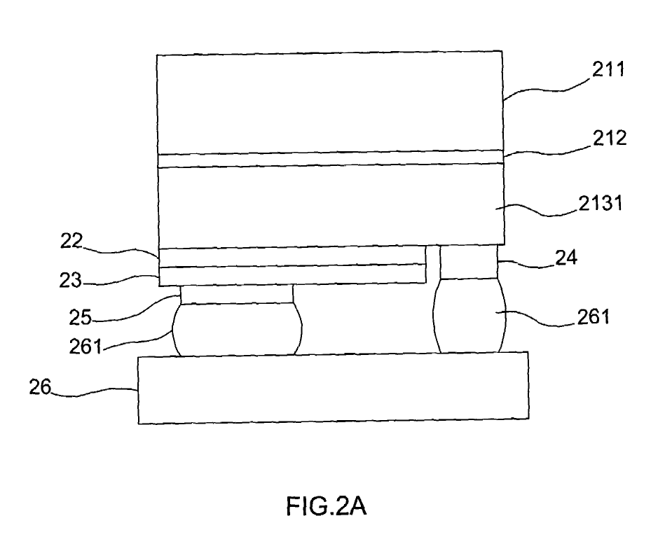

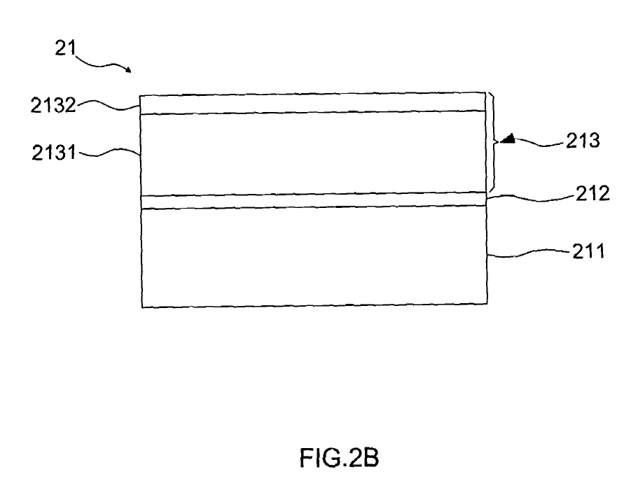

Please refer to FIG. 1, FIG. 2A and FIG. 2B, which are a view showing a flow chart of a first preferred embodiment according to the present invention, a structural view of the first preferred embodiment and a structural view of a p-side up gallium nitride (GaN) wafer. As shown in the figures, the present invention provides a method for fabricating a diode having a reflective electrode of an alloy metal. A first embodiment comprises the following steps:

(a) Obtaining a p-side up GaN wafer 11: A p-side up GaN wafer 21 is obtained at first. The p-side up GaN wafer 21 comprises a first substrate 211, a buffer layer 212 and an epitaxy layer (epi-layer) 213, where the first substrate 211 is a transparent substrate of sapphire, silicon carbide (SiC), gallium arsenide (GaAs), lithium gallium oxide (LiGaO₃) or aluminum nitride (AlN); the epi-layer 213 comprises an n-GaN 2131 and a p-GaN 2132; and the epi-layer 213 is made of GaAs, aluminum gallium nitride (AlGaN), AlN, gallium indium nitride (GaInN), aluminum gallium indium nitride (AlGaInN), indium nitride (InN), gallium indium arsenic nitride (GaInAsN) or gallium indium phosphorus nitride (GaInPN).

(b) Forming a p-GaN mesa 12: The epi-layer 213 of the p-side up GaN wafer 21 is processed through a lithography and an etching to form a p-GaN mesa 22 while exposing a part of the n-GaN layer 2131 of the epi-layer 213.

(c) Forming a high reflective ohmic contact alloy layer 13: An alloy metal layer is plated on the p-GaN mesa 22 and a thermal treatment is processed to a surface of the alloy metal layer so that a high reflective ohmic contact alloy layer 23 is formed. Therein, the alloy metal layer is made of nickel(Ni)/silver(Ag); and a trace amount of aluminum (Al) is further added into the alloy metal layer to improve a thermal stability of the high reflective ohmic contact alloy layer 23 without lowering a reflection rate of the high reflective ohmic contact alloy layer 23.

(d) Forming an n-pad 14: The exposed part of the n-GaN layer 2131 of the p-side up GaN wafer 21 is processed through a lithography and a metal depositing process so that an n-pad 24 is formed.

(e) Forming a p-pad 15: The high reflective ohmic contact alloy layer 23 is processed through a lithography and a metal depositing process so that a p-pad 25 is formed.

(f) Packaging a structure through a packaging process of flip chip 16: A structure formed through step (a) to step (e) is packaged on a second substrate 26 through a packaging process of flip chip with a metal material 261 to connect the second substrate 26 to the structure, where the metal material 261 is gold.

Thus the first embodiment of a novel method for fabricating a diode having a reflective electrode of an alloy metal is obtained.

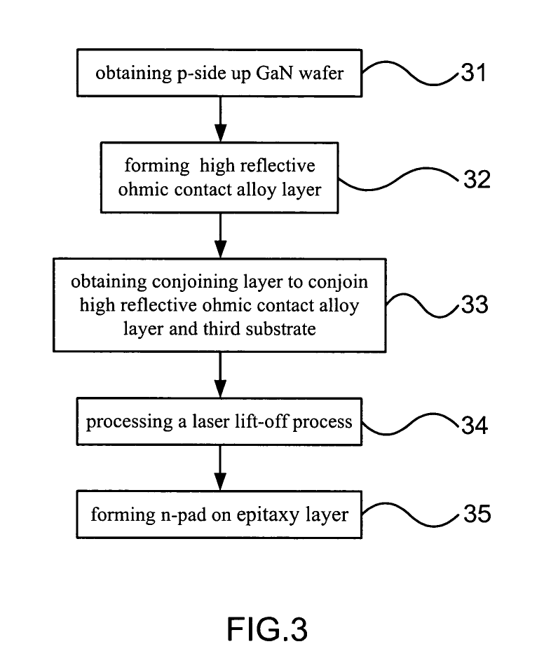

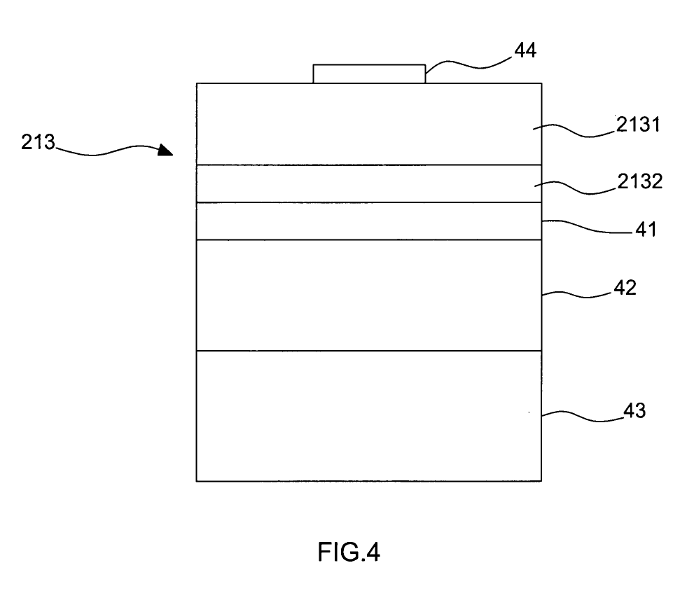

Please refer to FIG. 3 and FIG. 4, which are a flow-chart view and a structural view of a second preferred embodiment. As shown in the figures, a second embodiment of the present invention comprises the following steps:

(a1) Obtaining a p-side up GaN wafer 31: A p-side up GaN wafer 21 (as referred to FIG. 2B) is obtained. The p-side up GaN wafer 21 comprises a first substrate 211, a buffer layer 212 and an epi-layer 213, where the first substrate 211 is a transparent substrate of sapphire, SiC, GaAs, LiGaO₃ or AlN; the epi-layer 213 comprises an n-GaN 2131 and a p-GaN 2132; and the epi-layer 213 is made of GaAs, AlGaN, AlN, GaInN, AlGaInN, InN, GaInAsN or GaInPN.

(b1) Forming a high reflective ohmic contact alloy layer 32: The epi-layer 213 of the p-side up GaN wafer 21 is plated with an alloy metal layer and a high reflective ohmic contact alloy layer 41 is formed through a thermal treatment on a surface of the alloy metal layer, where the alloy metal layer is made of Ni/A g; and a trace amount of Al is further added into the alloy metal layer to improve a thermal stability of the high reflective ohmic contact alloy layer 41 without reducing a reflection rate of the high reflective ohmic contact alloy layer 41.

(c1) Obtaining a con joining layer 33: A conjoining layer 42 is obtained to con join the high reflective ohmic contact alloy layer 41 and a third substrate 43 having a good heat-dissipation.

(d1) Lifting the first substrate and the buffer layer off the epi-layer 34: A laser lift-off process is processed to lift the first substrate 211 and the buffer layer 212 off the epi-layer 213.

(e1) Forming an n-pad 35: The epi-layer 213 is processed through a lithography and a metal depositing process so that an n-pad 44 is formed.

Thus the second embodiment of the novel method for fabricating a diode having a reflective electrode of an alloy metal is obtained.

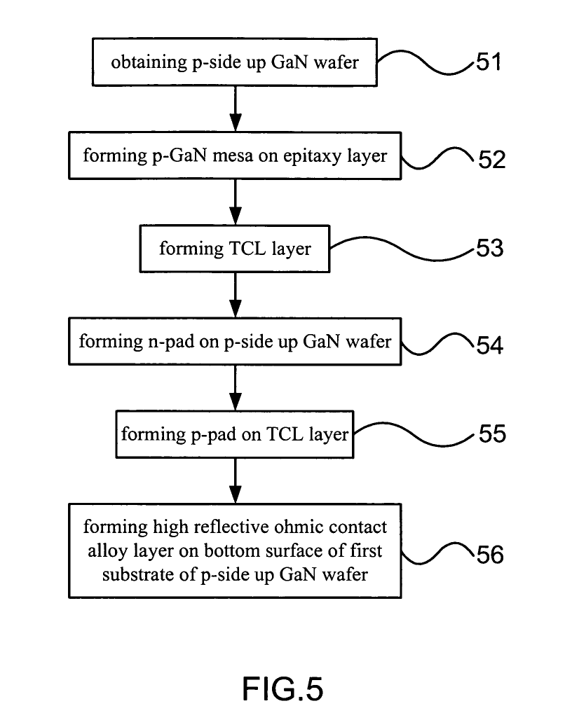

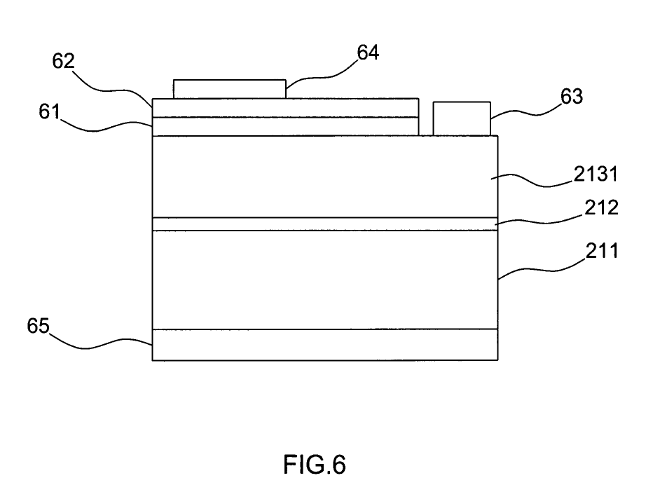

Please refer to FIG. 5 and FIG. 6, which are a flow-chart view and a structural view of a third preferred embodiment. As shown in the figures, a third embodiment of the present invention comprises the following steps:

(a2) Obtaining a p-side up GaN wafer 51: A p-side up GaN wafer 21 (as referred to FIG. 2B) is obtained. The p-side up GaN wafer 21 comprises a first substrate 211, a buffer layer 212 and an epi-layer 213, where the first substrate 211 is a transparent substrate of sapphire, SiC, GaAs, LiGaO₃ or AlN; the epi-layer 213 comprises an n-GaN 2131 and a p-GaN 2132; and the epi-layer 213 is made of GaAs, AlGaN, AlN, GaInN, AlGaInN, InN, GaInAsN or GaInPN.

(b2) Forming a p-GaN mesa 52: A p-GaN mesa 61 is formed through a lithography and an etching on the epi-layer 213 of the p-side up GaN wafer 21 while a part of the n-GaN layer 2131 of the epi-layer 213 is exposed out.

(c2) Forming a transparency conductive layer (TCL layer) 53: A TCL layer 62 is formed on the p-GaN mesa 61.

(d2) Forming an n-pad 54: An n-pad 63 is formed on the exposed part of the n-GaN layer 2131 of the p-side up GaN wafer 21.

(e2) Forming a p-pad 55: A p-pad 64 is formed through a lithography and a metal depositing process on the TCL layer 62.

(f2) Forming a high reflective ohmic contact alloy layer 56: An alloy metal layer is plated on a bottom surface of the first substrate 211 of the p-side up GaN wafer 21 and a high reflective ohmic contact alloy layer 65 is formed through a thermal treatment on a surface of the alloy metal layer, where the alloy metal layer is made of Ni/Ag; and a trace amount of Al is further added into the alloy metal layer to improve a thermal stability of the high reflective ohmic contact alloy layer 65 without lowering a reflection rate of the high reflective ohmic contact alloy layer 65.

Thus the third embodiment of the novel method for fabricating a diode having a reflective electrode of an alloy metal is obtained.

To sum up, the present invention is a method for fabricating a diode having a reflective electrode of an alloy metal, where a high reflective ohmic contact alloy layer fabricated in the present invention effectively improves a heat stability of the diode of the present invention by keeping from a metal aggregation on a pure metal layer after a thermal treatment.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method for fabricating a diode having a reflective electrode of an alloy metal, comprising steps of:
(a) obtaining a p-side up gallium nitride (GaN) wafer, said p-side up GaN wafer comprising a first substrate, a buffer layer and an epitaxy layer (epi-layer);
(b) obtaining a p-GaN mesa through a lithography and an etching on said epi-layer;
(c) plating an alloy metal layer on said p-GaN mesa and processing a thermal treatment to a surface of said alloy metal layer to obtain a high reflective ohmic contact alloy layer;
(d) obtaining an n-pad through a lithography and a metal depositing process on said p-side up GaN wafer;
(e) obtaining a p-pad through a lithography and a metal depositing process on said high reflective ohmic contact alloy layer; and
(f) processing a packaging process of flip chip to a structure obtained through step (a) to step (e), said structure being packaged on a second substrate, said second substrate connecting to said structure with a metal material.

2. The method according to claim 1,
wherein said first substrate is a transparent substrate made of a material selected from a group consisting of sapphire silicon carbide (SiC), gallium arsenide (GaAs), lithium gallium oxide (LiGaO₃) and aluminum nitride (AlN).

3. The method according to claim 1,
wherein said epi-layer comprises an n-GaN and a p-GaN.

4. The method according to claim 1,
wherein said epi-layer is made of a material selected from a group consisting of GaAs, aluminum gallium nitride (AlGaN), AlN, gallium indium nitride (GaInN), aluminum gallium indium nitride (AlGaInN), indium nitride (InN), gallium indium arsenic nitride (GaInAsN) and gallium indium phosphorus nitride (GaInPN).

5. The method according to claim 1,
wherein said metal material is gold.

6. The method according to claim 1
wherein said alloy metal layer is made of nickel(Ni)/silver(Ag).

7. The method according to claim 6,
wherein said alloy metal layer is further added with a metal of aluminum (Al).

8. A method for fabricating a diode having a reflective electrode of an alloy metal, comprising steps of:
(a1) obtaining a p-side up GaN wafer, said p-side up GaN wafer comprising a first substrate, a buffer layer and an epi-layer;
(b1) plating an alloy metal layer on said epi-layer and processing a thermal treatment to a surface of said alloy metal layer to obtain a high reflective ohmic contact alloy layer;
(c1) obtaining a con joining layer to con join said high reflective ohmic contact alloy layer and a third substrate;
(d1) processing a laser lift-off process to lift said first substrate and said buffer layer off said epi-layer; and
(e1) obtaining an n-pad through a lithography and a metal depositing process on said epi-layer.

9. The method according to claim 8,
wherein said first substrate is a transparent substrate made of a material selected from a group consisting of sapphire, SiC, GaAs, LiGaO₃ and AlN.

10. The method according to claim 8,
wherein said epi-layer comprises an n-GaN and a p-GaN.

11. The method according to claim 8,
wherein said epi-layer is made of a material selected from a group consisting of GaAs, AlGaN, AlN, GaInN, AlGaInN, InN, GaInAsN and GaInPN.

12. The method according to claim 8,
wherein said alloy metal layer is made of Ni/Ag.

13. The method according to claim 12,
wherein said alloy metal layer is further added with a metal of Al.

14. A method for fabricating a diode having a reflective electrode of an alloy metal, comprising steps of:
(a2) obtaining a p-side up GaN wafer, said p-side up GaN wafer having a first substrate, a buffer layer and an epi-layer;
(b2) obtaining a p-GaN mesa through a lithography and an etching on said epi-layer;
(c2) obtaining a transparency conductive layer (TCL layer) on said p-GaN mesa;
(d2) obtaining an n-pad through a lithography and a metal depositing process on said p-side up GaN wafer;
(e2) obtaining a p-pad through a lithography and a metal depositing process on said TCL layer; and
(f2) plating an alloy metal layer on a bottom surface of said first substrate and processing a thermal treatment to a surface of said alloy metal layer to obtain a high reflective ohmic contact alloy layer.

15. The method according to claim 14,
wherein said first substrate is a transparent substrate made of a material selected from a group consisting of sapphire, SiC, GaAs, LiGaO₃ and AlN.

16. The method according to claim 14,
wherein said epi-layer comprises an n-GaN and a p-GaN.

17. The method according to claim 14,
wherein said epi-layer is made of a material selected from a group consisting of GaAs, AlGaN, AlN GaInN, AlGaInN, InN, GaInAsN and GaInPN.

18. The method according to claim 14,
wherein said alloy metal layer is made of Ni/Ag.

19. The method according to claim 18,
wherein said alloy metal layer is further added with a metal material of Al.
